(19) United States
(12) Patent Application Publication
(10) Pub. No.: US 2026/0347993 A1
(43) Pub. Date: Nov. 5, 2026

(54) MASK FOR DEPOSITION, METHOD OF MANUFACTURING MASK FOR DEPOSITION, AND ELECTRONIC DEVICE

(71) Applicant: Samsung Display Co., Ltd., Yongin-si (KR)

(72) Inventor: Sung Woon KIM, Yongin-si (KR)

(21) Appl. No.: 19/379,109

(22) Filed: Nov. 4, 2025

(30) Foreign Application Priority Data
Apr. 30, 2025 (KR) 10-2025-0057666

(51) Int. Cl. C23C 14/04; H10K 71/16

(52) U.S. Cl. CPC C23C 14/042; H10K 71/166

(57) ABSTRACT

A mask for deposition includes a mask substrate having a first substrate opening and a second substrate opening defined therein, an oxide layer arranged on the mask substrate, a first pattern layer arranged on the oxide layer and having a pattern layer opening defined therein, the pattern layer opening overlapping with the first substrate opening, a second pattern layer arranged in the second substrate opening, and an alignment mark arranged in the second substrate opening.

### CROSS-REFERENCE TO RELATED APPLICATION

The present application claims priority to and the benefit of Korean Patent Application Number 10-2025-0057666, filed on Apr. 30, 2025, in the Korean Intellectual Property Office, the entire content of which is incorporated herein by reference.

### BACKGROUND

### 1. Field

One or more embodiments of the present disclosure relate to a mask for deposition, a method of manufacturing the mask for deposition, and an electronic device.

### 2. Description of the Related Art

With the rapid advancement of information technology, the importance of display devices, which serve as a medium for connection and interaction between a user and information, has become increasingly significant. Accordingly, research and development of display devices has been continuously conducted to meet various user needs.

An organic light emitting display device, which is an example of a display device, may be used in a mobile device such as a smartphone, a computer, and/or a tablet personal computer, or in an electronic device such as a television, an outdoor billboard, and/or an exhibition display.

The organic light emitting display device may include an anode electrode, a cathode electrode, and an organic light emitting layer interposed therebetween, sequentially arranged on a substrate. The organic light emitting layer may be formed using a mask for deposition.

### SUMMARY

One or more aspects of embodiments of the present disclosure are directed toward a mask for deposition and a method of manufacturing the mask for deposition that may improve the reliability of a deposition process.

One or more aspects of embodiments of the present disclosure are directed toward a mask for deposition and a method of manufacturing the mask for deposition that may reduce the risk of damage during an alignment process with a deposition target.

One or more aspects of embodiments of the present disclosure are directed toward an electronic device manufactured using the mask for deposition and having improved reliability.

Additional aspects will be set forth in part in the description which follows and, in part, will be apparent from the description, or may be learned by practice of the presented embodiments.

According to one or more embodiments of the present disclosure, a mask for deposition includes a mask substrate having a first substrate opening and a second substrate opening defined therein, an oxide layer on (e.g., arranged on) the mask substrate, a first pattern layer on (e.g., arranged on) the oxide layer and having a pattern layer opening defined therein, the pattern layer opening overlapping with the first substrate opening, a second pattern layer in (e.g., arranged in) the second substrate opening, and an alignment mark in (e.g., arranged in) the second substrate opening.

In one or more embodiments, the second substrate opening may be defined through the mask substrate.

In one or more embodiments, the alignment mark may be arranged (e.g., positioned) lower than the pattern layer opening.

In one or more embodiments, the second pattern layer may be arranged (e.g., positioned) lower than the pattern layer opening.

In one or more embodiments, the alignment mark may not be in contact with the mask substrate.

In one or more embodiments, in a cross-section view, the alignment mark may be between (e.g., arranged between) an upper surface and a lower surface of the mask substrate.

In one or more embodiments, the first pattern layer and the second pattern layer may be formed in a same process.

In one or more embodiments, the oxide layer may include a silicon oxide layer (SiOₓ), and the first pattern layer and the second pattern layer may each include silicon nitride (SiNₓ)_{.}

In one or more embodiments, a lower surface of the second pattern layer may be in contact with an upper surface of the alignment mark.

In one or more embodiments, the alignment mark may include metal (e.g., a metal).

In one or more embodiments, an upper surface of the second pattern layer may be in contact with a lower surface of the alignment mark.

In one or more embodiments, an alignment opening passing through the second pattern layer may be defined in the second pattern layer, and the alignment mark may be the alignment opening.

According to one or more embodiments of the present disclosure, a method of manufacturing a mask for deposition includes forming a groove in a base mask substrate, forming a base oxide layer on the base mask substrate, forming a base pattern layer on the base oxide layer, forming an alignment mark in the groove, and etching the base mask substrate to form a mask substrate having a first substrate opening and a second substrate opening defined therein, wherein the alignment mark is arranged in the second substrate opening.

In one or more embodiments, the base pattern layer may include: a first pattern layer on (e.g., arranged on) the base oxide layer, and a second pattern layer in (e.g., arranged in) the groove.

The method may further include etching the base pattern layer, the base pattern layer may be etched to define a pattern layer opening through which a deposition material passes, and the alignment mark may be arranged lower than the pattern layer opening.

In one or more embodiments, the alignment mark may be formed before the base pattern layer is formed, and an upper surface of the alignment mark may be in contact with a lower surface of the second pattern layer.

In one or more embodiments, the alignment mark may be formed after the base pattern layer is formed, and a lower surface of the alignment mark may be in contact with an upper surface of the second pattern layer.

In one or more embodiments, the alignment mark may include metal (e.g., a metal).

In one or more embodiments, the etching of the base pattern layer may further include etching the second pattern layer to form an alignment opening, and the alignment mark may be the alignment opening.

According to one or more embodiments of the present disclosure, an electronic device includes a display device including a display panel and a processor, wherein the display panel includes a light emitting layer, and wherein the light emitting layer is deposited using the mask for deposition.

For example, the embodiments described herein provide a mask for deposition and a corresponding manufacturing method that enhance alignment accuracy, reduce the likelihood of damage during handling, and improve the overall reliability of the deposition process. By incorporating features such as multiple substrate openings, patterned layers, and/or strategically positioned alignment marks, the disclosed mask structure facilitates precise material deposition for forming light emitting layers in display panels. These improvements enable the production of high-quality electronic devices, including display devices, that exhibit enhanced performance and durability.

### BRIEF DESCRIPTION OF DRAWINGS

The accompanying drawings are included to provide a further understanding of the present disclosure and are incorporated in and constitute a part of this disclosure. The drawings illustrate example embodiments of the disclosure and, together with the description, serve to explain principles of the present disclosure. The above and other aspects and features of embodiments according to the present disclosure will become more apparent from the following description of, in further detail, aspects of one or more embodiments thereof with reference to the accompanying drawings, in which:

FIG. 1 is a schematic plan view illustrating a mask for deposition according to one or more embodiments of the present disclosure;

FIG. 2 is a schematic diagram illustrating an embodiment of a deposition apparatus including the mask for deposition of FIG. 1 according to one or more embodiments of the present disclosure;

FIG. 3 is a schematic cross-sectional view illustrating a first region of FIG. 2 according to a first embodiment of the present disclosure;

FIG. 4 is a schematic cross-sectional view showing a first region of FIG. 2 according to a second embodiment of the present disclosure;

FIG. 5 is a schematic cross-sectional view showing a first region of FIG. 2 according to a third embodiment of the present disclosure;

FIG. 6 is a flowchart illustrating a method of manufacturing a mask for deposition of FIG. 3 according to one or more embodiments of the present disclosure;

FIGS. 7-12 are schematic cross-sectional views of a method of manufacturing a mask for deposition of FIG. 6 according to one or more embodiments of the present disclosure;

FIG. 13 is a flowchart illustrating a method of manufacturing a mask for deposition of FIG. 4 according to one or more embodiments of the present disclosure;

FIGS. 14 - 17 are schematic cross-sectional views for illustrating a method of manufacturing a mask for deposition of FIG. 13 according to one or more embodiments of the present disclosure;

FIG. 18 is a flowchart illustrating a method of manufacturing a mask for deposition of FIG. 5 according to one or more embodiments of the present disclosure;

FIGS. 19 and 20 are schematic cross-sectional views of a method of manufacturing a mask for deposition of FIG. 18 according to one or more embodiments of the present disclosure;

FIG. 21 is a schematic plan view illustrating a display device according to one or more embodiments of the present disclosure;

FIG. 22 is a schematic plan view illustrating sub-pixels according to one or more embodiments of the present disclosure;

FIG. 23 is a schematic cross-sectional view cut through the I-I’ lines in FIG. 22 according to one or more embodiments of the present disclosure;

FIG. 24 is a flowchart illustrating a method of manufacturing a display device according to one or more embodiments of the present disclosure;

FIG. 25 is a block diagram of the electronic device according to one or more embodiments of the present disclosure; and

FIG. 26 shows schematic views of electronic devices according to one or more embodiments of the present disclosure.

### DETAILED DESCRIPTION

Herein, some example embodiments of the present disclosure will be described in further detail with reference to the accompanying drawings. It should be noted that in the following description, the parts necessary to understand the operation according to the present disclosure will be described, and descriptions of other parts may not be provided in order to not obscure the gist of the present disclosure. In addition, the present disclosure is not limited to the embodiments described herein and may be embodied in other forms. The embodiments described herein are provided to explain the present disclosure in further detail so as to enable those skilled in the art to easily implement the technical idea of the present disclosure.

Throughout the disclosure, in an embodiment in which a portion is “connected” to another portion, the embodiment includes not only an embodiment in which the portion is directly connected to the another portion but also embodiments in which the portion is indirectly connected to the another portion with one or more other elements interposed therebetween. Terms used herein are for describing example embodiments and are not intended to limit the present disclosure. Throughout the disclosure, the terms "include(s)/including," “comprise(s)/comprising,” and/or "has(have)/having" and/or the like are intended to designate the presence of the features, numbers, steps, actions, components, parts, or combinations thereof described in the disclosure, and are not to be understood as precluding the possibility of the presence or addition of one or more other features, numbers, steps, actions, components, parts, or combinations thereof. Additionally, the terms “comprise(s)/comprising,” “include(s)/including,” “have/has/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof. In addition, expressions of “at least one of X, Y, and Z,” “at least one of X, Y, or Z,” “at least one selected from among X, Y, and Z,” and/or “at least one selected from the group consisting of X, Y, and Z” may be construed as X only, Y only, Z only, any combination of two or more selected from among X, Y, and Z, such as, for instance, XYZ, XYY, YZ, and ZZ, or any variation thereof. The term “and/or,” “or,” or “/” may include any and all combinations of one or more of the associated listed items.

Here, terms such as “first” and “second” may be used to describe one or more suitable components, but these components are not limited to these terms. These terms are used to distinguish one component from another component. Therefore, a first component may be referred to as a second component, and similarly, a second component may be referred to as a first component, without departing from the scope and teachings disclosed herein. In the following description, the singular expressions include plural expressions unless the context clearly dictates otherwise. For example, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure.

Spatially relative terms, such as “under,” “on,” and/or the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, if (e.g., when) a device shown in the drawing is turned upside down, elements depicted as being positioned “under” other elements or features are positioned in a direction “on” the other elements or features. Therefore, in one or more embodiments, the term “under” may include both (e.g., simultaneously) directions of on and under. In addition, the device may face in other directions (for example, rotated 90 degrees or in other directions) and, thus, the spatially relative terms used herein are interpreted according thereto.

Various embodiments are described with reference to drawings schematically illustrating example or ideal embodiments. Accordingly, it will be expected that shapes may vary, for example, according to tolerances and/or manufacturing techniques. Therefore, the embodiments disclosed herein are not to be construed as being limited to shown specific shapes, and are to be interpreted as including, for example, changes in shapes that may occur as a result of manufacturing. As described above, the shapes shown in the drawings may not show actual or identical shapes of areas of a device, and embodiments of the present disclosure are not limited thereto.

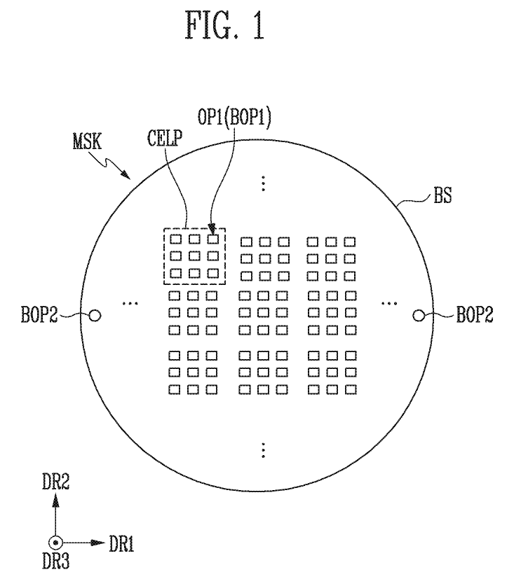

With reference to FIGS. 1 - 3, a mask for deposition (hereinafter, referred to as a “deposition mask MSK” and used interchangeable) according to a first embodiment of the present disclosure will be described in more detail.

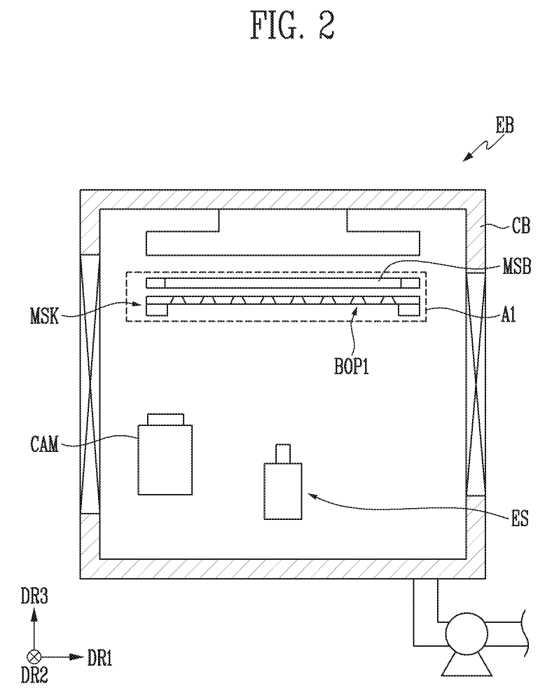

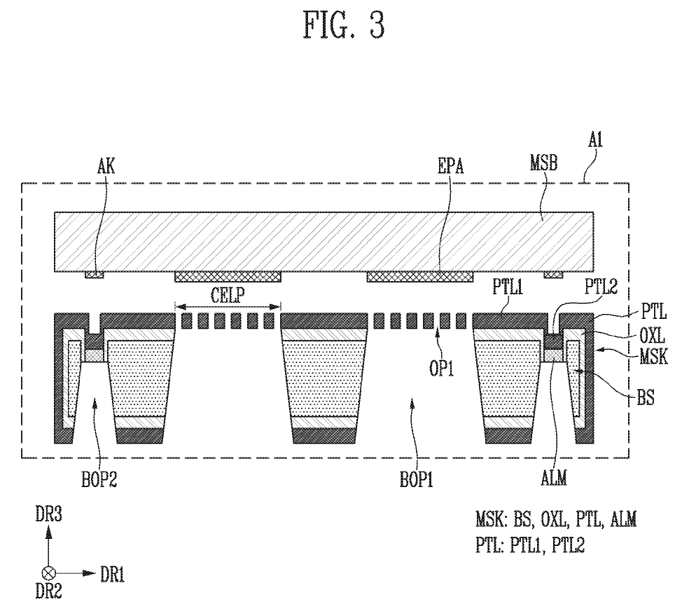

FIG. 1 is a schematic plan view illustrating a deposition mask MSK according to one or more embodiments of the present disclosure. FIG. 2 is a schematic diagram illustrating an embodiment of a deposition apparatus including the deposition mask MSK of FIG. 1 according to one or more embodiments. FIG. 3 is a schematic cross-sectional view illustrating a first region of FIG. 2 according to the first embodiment of the present disclosure.

Referring to FIG. 1, the deposition mask MSK may include a mask substrate BS.

The mask substrate BS may be a wafer substrate. For example, in one or more embodiments, the mask substrate BS may be a wafer substrate including silicon (Si). In one or more embodiments, the mask substrate BS may have a circular shape in plan view. However, the planar shape of the mask substrate BS is not limited thereto. The mask substrate BS may have one or more suitable planar shapes.

The deposition mask MSK may include a cell opening region CELP. The deposition mask MSK may be aligned to face a deposition target (e.g., MSB in FIG. 2). The deposition mask MSK may block a deposition material in some regions and may not block the deposition material in other regions. Accordingly, the deposition material may be selectively deposited only on a set or predetermined region of the deposition target. The cell opening region CELP may be a region in which the other some regions where the deposition material is not blocked are provided.

For example, the cell opening region CELP may be provided with a plurality of pattern layer openings OP1, and one first substrate opening BOP1 (see FIG. 2) overlapping therewith. As used herein, “overlapping” may be defined as “overlapping in a plan view,” and the plane may be defined as a plane on which the deposition mask MSK is arranged.

At least one selected from among the plurality of pattern layer openings OP1 and the first substrate opening BOP1 may be connected to each other (e.g., fluidly connected to allow the deposition material to pass through). The deposition material may pass through the first substrate opening BOP1 and the plurality of pattern layer openings OP1 and be provided to the deposition target.

Using a single deposition mask MSK, a plurality of deposition targets may be deposited concurrently (e.g., simultaneously). A plurality of cell opening regions CELP may be provided accordingly. For example, in one or more embodiments, the plurality of cell opening regions CELP may be arranged along a first direction DR1 and a second direction DR2 intersecting the first direction DR1, and may be spaced and/or apart (e.g., spaced apart or separated) from each other. If (e.g., when) the plurality of cell opening regions CELP are provided, each of the plurality of cell opening regions CELP may be provided with the one first substrate opening BOP1, and the plurality of pattern layer openings OP1 overlapping with corresponding the first substrate opening BOP1.

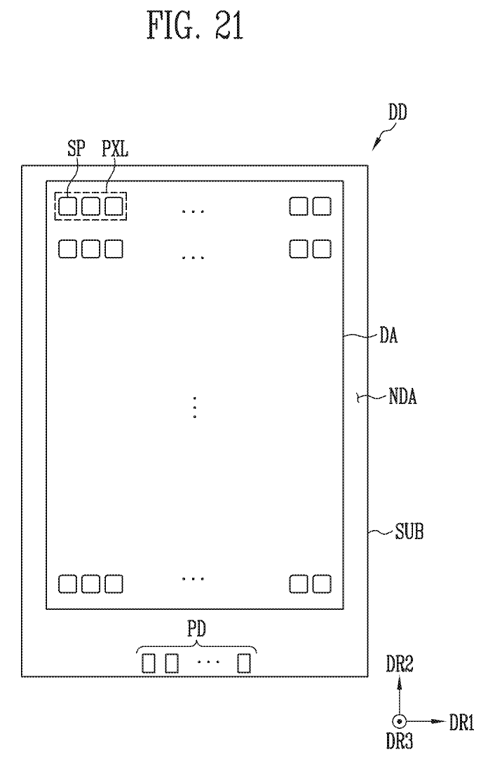

Referring to FIGS. 1 and 2, a deposition apparatus EB according to one or more embodiments may include a chamber CB, a deposition source ES, a camera CAM, and the deposition mask MSK. The deposition apparatus EB may be for manufacturing a display device DD (see FIG. 21).

The chamber CB may have an interior space. The interior space of the chamber CB may be a workspace provided for a deposition process. An object which is the subject of the deposition may be received (or arranged) in the interior of the chamber CB. For example, a mother substrate MSB may be arranged in the interior of the chamber CB.

The deposition source ES may be arranged inside the chamber CB. The deposition source ES may receive a deposition material and may supply the deposition material to the interior space of the chamber CB. The deposition material may include a material which forms a set or predetermined pattern layer (e.g., a light emitting layer) on the mother substrate MSB. The deposition source ES may apply energy (e.g., thermal energy, light energy, or vibrational energy) to the deposition material to vaporize or sublimate the deposition material. For example, in one or more embodiments, the deposition source ES may include an internal heater, and operation of the heater may melt or sublimate the deposition material by heating the deposition material inside the deposition source ES. The deposition source ES may be replaceable. The deposition source ES may be replaced with a new deposition source if (e.g., when) the deposition material stored therein is exhausted.

Referring to FIGS. 1 - 3, the mother substrate MSB and the deposition mask MSK may be arranged in a first region A1. The deposition mask MSK may be arranged between the mother substrate MSB and the deposition source ES.

The deposition mask MSK may include the mask substrate BS, an oxide layer OXL arranged on the mask substrate BS, a pattern layer PTL arranged on the oxide layer OXL, and an alignment mark ALM arranged within an opening in the mask substrate BS.

The mask substrate BS may define the first substrate opening BOP1 and a second substrate opening BOP2. The first substrate opening BOP1 and the second substrate opening BOP2 may penetrate the mask substrate BS in a third direction DR3 (e.g., a thickness direction). The first substrate opening BOP1 may overlap with the cell opening region CELP. The second substrate opening BOP2 may be arranged further toward the periphery of the mask substrate BS than the first substrate opening BOP1. For example, in one or more embodiments, the second substrate opening BOP2 may be arranged closer to an edge of the mask substrate BS than the first substrate opening BOP1.

The oxide layer OXL may be arranged on the mask substrate BS. The oxide layer OXL may cover at least a portion of the mask substrate BS. For example, the oxide layer OXL may be in contact with at least a portion of the mask substrate BS. In a region where the second substrate opening BOP2 is defined, at least a portion of the oxide layer OXL may be in contact with the mask substrate BS. For example, in a region overlapping with the second substrate opening BOP2, at least a portion of the oxide layer OXL may be in contact with a side surface of the mask substrate BS. At least a portion of the oxide layer OXL may be arranged within the second substrate opening BOP2.

According to one or more embodiments, the oxide layer OXL may be a silicon oxide layer (SiOₓ) including silicon. However, embodiments of the present disclosure are not limited thereto.

The pattern layer PTL may be arranged on the oxide layer OXL. The pattern layer PTL may cover at least a portion of the oxide layer OXL. For example, the pattern layer PTL may be in contact with at least a portion of the oxide layer OXL.

The pattern layer PTL may include a first pattern layer PTL1 arranged on the oxide layer OXL and defining the pattern layer openings OP1 and a second pattern layer PTL2 arranged within the second substrate opening BOP2. For example, the first pattern layer PTL1 may be a portion of the pattern layer PTL arranged in a same layer as the pattern layer openings OP1 in the third direction DR3. For example, the second pattern layer PTL2 may be a portion of the pattern layer PTL arranged lower than the pattern layer openings OP1 in the third direction DR3, and arranged within the second substrate opening BOP2. A top surface of the second pattern layer PTL2 may be arranged at a different height from a top surface of the first pattern layer PTL1. For example, in one or more embodiments, the top surface of the first pattern layer PTL1 may be arranged on the oxide layer OXL, and the top surface of the second pattern layer PTL2 may form a step with the top surface of the first pattern layer PTL1. For example, in one or more embodiments, the first pattern layer PTL1 and the second pattern layer PTL2 may be connected to each other, and a step of the pattern layer PTL may be formed in the region where the first pattern layer PTL1 and the second pattern layer PTL2 are connected. At least a portion of the first pattern layer PTL1 may overlap with the mask substrate BS in a plan view. The second pattern layer PTL2 may not overlap with the mask substrate BS in a plan view.

The second pattern layer PTL2 may be in contact with the oxide layer OXL extending in a direction in which the second substrate opening BOP2 extends (e.g., in the third direction DR3). For example, the second pattern layer PTL2 may be in contact with one surface of the oxide layer OXL (e.g., a side surface of the oxide layer OXL) defined along the second direction DR2 and the third direction DR3. The second pattern layer PTL2 may be in contact with the alignment mark ALM.

The first pattern layer PTL1 and the second pattern layer PTL2 may be formed in a same process. The first pattern layer PTL1 and the second pattern layer PTL2 may include a same material. In accordance with one or more embodiments, the pattern layer PTL (the first pattern layer PTL1 and the second pattern layer PTL2) may include silicon nitride (SiNₓ). However, embodiments of the present disclosure are not limited thereto.

The alignment mark ALM may be arranged within the second substrate opening BOP2. For example, the alignment mark ALM may be accommodated within the second substrate opening BOP2. In a cross-section view, the alignment mark ALM may be arranged (e.g., positioned) between a top surface and a bottom surface of the mask substrate BS. The alignment mark ALM may be arranged lower than the pattern layer opening OP1 in the third direction DR3. For example, the alignment mark ALM may not protrude further in the third direction DR3 than the pattern layer opening OP1. For example, a top surface of the alignment mark ALM may be arranged lower than the top surface of the first pattern layer PTL1 in which the pattern layer opening OP1 is defined.

The alignment mark ALM may be arranged under the second pattern layer PTL2. For example, in the mask MSK according to the first embodiment, the second pattern layer PTL2 may be arranged on the alignment mark ALM.

The alignment mark ALM may not be in contact with the mask substrate BS. A bottom surface of the alignment mark ALM may be exposed, a side surface of the alignment mark ALM may be in contact with the oxide layer OXL, and the top surface of the alignment mark ALM may be in contact with a bottom surface of the second pattern layer PTL2. However, embodiments of the present disclosure are not limited thereto. According to one or more embodiments, the top surface of the alignment mark ALM may be in contact with the bottom surface of the second pattern layer PTL2, and the side surface of the alignment mark ALM may not be in contact with the oxide layer OXL.

The alignment mark ALM may aid in the alignment of the deposition mask MSK and the mother substrate MSB. For example, the alignment mark ALM on the deposition mask MSK may be recognized and allow the deposition mask MSK to be positioned at an appropriate or suitable location on the mother substrate MSB if (e.g., when) the deposition mask MSK is moved in the first direction DR1, the second direction DR2, and the third direction DR3, or if (e.g., when) the deposition mask MSK is rotated.

According to one or more embodiments, the alignment mark ALM may include metal (e.g., a metal). For example, the alignment marks ALM may include iron (Fe), copper (Cu), aluminum (Al), gold (Au), silver (Ag), titanium (Ti), zinc (Zn), lead (Pb), and/or the like. However, embodiments of the present disclosure are not limited thereto.

The alignment mark ALM according to one or more embodiments of the present disclosure may not protrude further in the third direction DR3 than the pattern layer opening OP1, and the risk of the alignment mark ALM contacting the mother substrate MSB during alignment of the deposition mask MSK and the mother substrate MSB may be reduced. If (e.g., when) the alignment mark ALM protrudes further than the pattern layer opening OP1 or is arranged on a same layer as the pattern layer opening OP1, the alignment mark ALM may come into contact with another configuration (e.g., the mother substrate MSB) during the process of moving the deposition mask MSK for alignment of the deposition mask MSK and the mother substrate MSB. If (e.g., when) the alignment mark ALM contacts another configuration (e.g., the mother substrate MSB), the alignment mark ALM may be damaged, or a portion of the metal included in the alignment mark ALM may be transferred onto the mother substrate MSB. The reliability of the deposition process may be reduced, thereby reducing the reliability of the display device DD. In contrast, the alignment mark ALM according to one or more embodiments of the present disclosure may not contact the mother substrate MSB during the alignment process of the deposition mask MSK and the mother substrate MSB, and the reliability of the deposition process may be improved.

One cell opening region CELP may correspond to a deposition area EPA. The one cell opening region CELP may be provided with the plurality of pattern layer openings OP1 which penetrate the deposition mask MSK in the third direction DR3. Further, the cell opening region CELP may be provided with the first substrate opening BOP1. For example, the pattern layer PTL may be defined with the plurality of pattern layer openings OP1 penetrating the pattern layer PTL in the third direction DR3, and the mask substrate BS may be defined with the first substrate opening BOP1 penetrating the mask substrate BS in the third direction DR3. In each of the plurality of cell opening regions CELP, the (one) first substrate opening BOP1 and at least one selected from among the pattern layer openings OP1 may overlap. The one first substrate opening BOP1 and the plurality of pattern layer openings OP1 may be formed integrally (e.g., connected integrally), and accordingly, the deposition material may be provided to the deposition area EPA via the first substrate opening BOP1 and the pattern layer openings OP1.

The camera CAM may be arranged on an inner surface of the chamber CB, may be oriented toward the deposition mask MSK and the mother substrate MSB, and may take pictures. For example, the mother substrate MSB may include a mother substrate alignment mark AK arranged on one side of the mother substrate MSB. The camera CAM may image the mother substrate alignment mark AK and the alignment mark ALM. For example, the camera CAM may capture an image to determine whether the mother substrate alignment mark AK and the alignment mark ALM are aligned. Based on the determination, the deposition mask MSK may be aligned based on the captured image. The camera CAM may be one of a variety of cameras currently suitable in the art, including a charge-coupled device (CCD) camera.

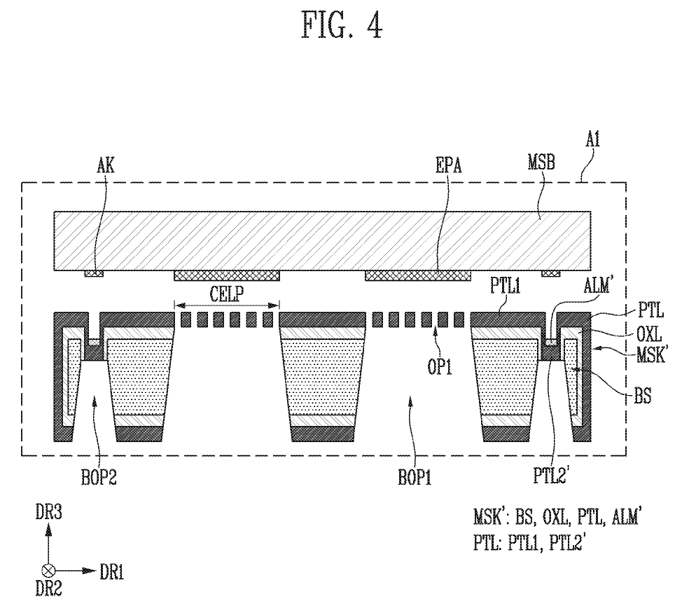

Hereinafter, with reference to FIG. 4, a mask for deposition (hereinafter, referred to as a “deposition mask MSK’”) according to a second embodiment of the present disclosure will be described.

FIG. 4 is a schematic cross-sectional view illustrating the first region of FIG. 2 according to the second embodiment. Hereinafter, descriptions of content overlapping with the foregoing will be briefly provided or omitted.

Referring to FIG. 4, in accordance with one or more embodiments, an alignment mark ALM’ may be arranged on a second pattern layer PTL2’. A top surface of the alignment mark ALM’ may be exposed, a side surface of the alignment mark ALM’ may be in contact with a side surface of the second pattern layer PTL2’, and a bottom surface of the alignment mark ALM’ may be in contact with a top surface of the second pattern layer PTL2’.

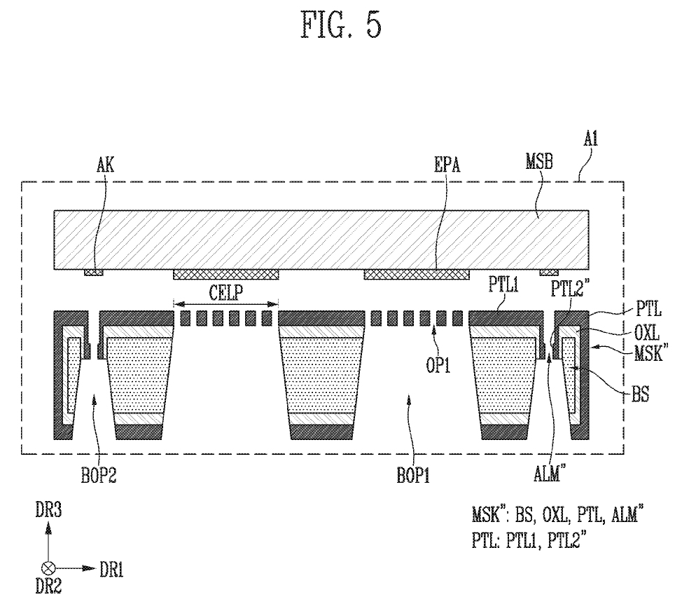

Hereinafter, with reference to FIG. 5, a mask for deposition (hereinafter, referred to as a deposition mask MSK”) according to a third embodiment of the present disclosure will be described.

FIG. 5 is a schematic cross-sectional view showing the first region of FIG. 2 according to the third embodiment. Descriptions of content overlapping with the foregoing will be briefly provided or omitted.

Referring to FIG. 5 according to one or more embodiments, an alignment opening may be defined in the second pattern layer PTL2”. For example, an opening which penetrates the second pattern layer PTL2” in the third direction DR3 may be defined in the second pattern layer PTL2”. An alignment mark ALM” may correspond to the alignment opening penetrating the second pattern layer PTL2” in the third direction DR3.

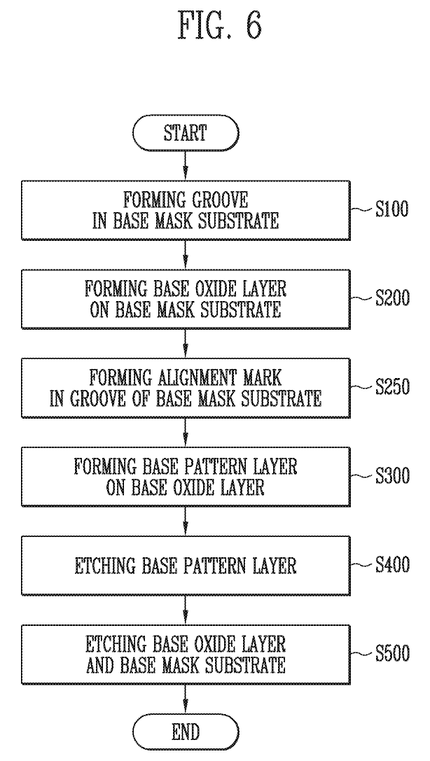

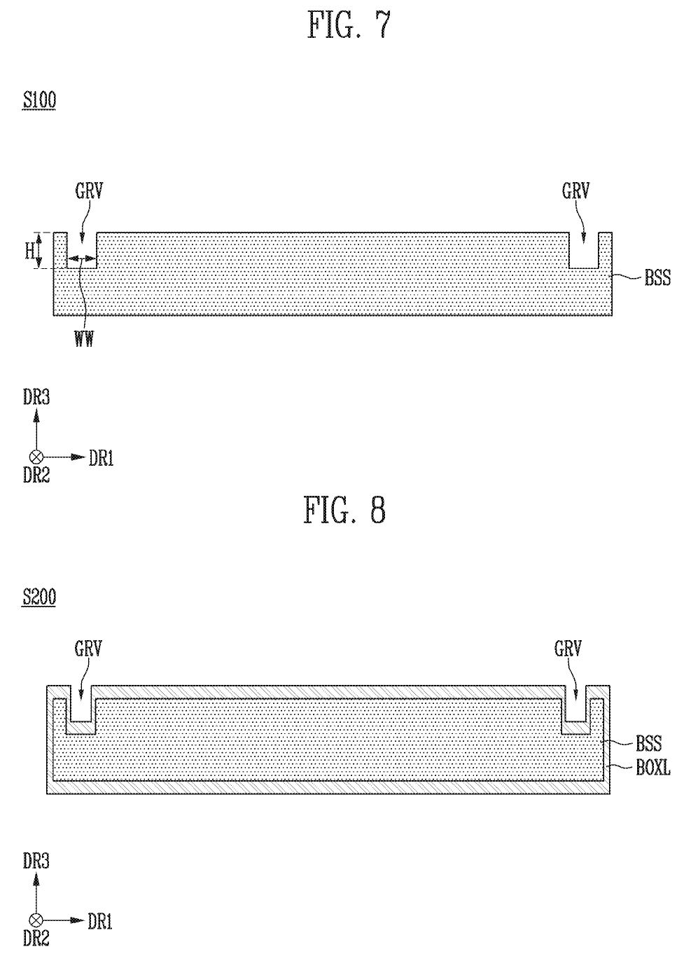

Hereinafter, a method of manufacturing the deposition mask MSK will be described with reference to FIGS. 6 - 12. FIG. 6 is a flowchart illustrating a method of manufacturing the deposition mask MSK of FIG. 3 according to one or more embodiments of the present disclosure. FIGS. 7 - 12 are schematic cross-sectional views of the method of manufacturing the deposition mask MSK of FIG. 6.

Referring to FIG. 6, the method of manufacturing the deposition mask MSK may include step (e.g., act or task) S100 of forming a groove in a base mask substrate, step (e.g., act or task) S200 of forming a base oxide layer on the base mask substrate, step (e.g., act or task) S250 of forming an alignment mark in the groove of the base mask substrate, step (e.g., act or task) S300 of forming a base pattern layer on the base oxide layer, step (e.g., act or task) S400 of etching the base pattern layer, and step (e.g., act or task) S500 of etching the base oxide layer and the base mask substrate.

Referring to FIG. 7, step (e.g., act or task) S100 of forming the groove in the base mask substrate may include etching a portion of a top surface of a base mask substrate BSS to form a groove GRV. The base mask substrate BSS may be for forming the mask substrate BS, and may be etched to form the mask substrate BS in the late steps.

Hereinafter, an etching process may include one or more suitable types (kinds) of etching processes (e.g., wet etching, dry etching, and/or the like), and a deposition process may include one or more suitable types (kinds) of deposition processes (e.g., sputtering, chemical vapor deposition, and/or the like). However, embodiments of the present disclosure are not limited thereto.

The groove GRV may have a width WW and a height H. The height H of the groove GRV may be smaller than the width WW of the groove GRV. According to one or more embodiments, the height H of the groove GRV may be from about 1 micrometer (μm) to about 3 μm. According to one or more embodiments, the width WW of the groove GRV may be from about 1 millimeter (mm) to about 3 mm. However, embodiments of the present disclosure are not limited thereto. The width WW and the height H of the groove GRV may be varied depending on the deposition mask MSK.

The groove GRV may not completely penetrate the base mask substrate BSS in the third direction DR3. For example, the height H of the groove GRV may be smaller than a thickness of the base mask substrate BSS.

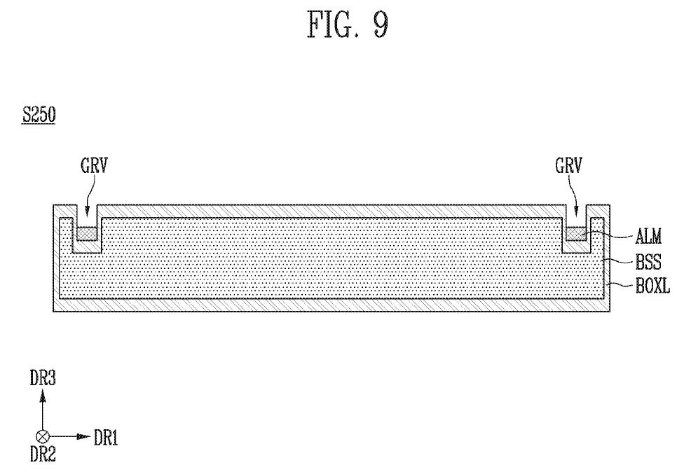

Referring to FIG. 8, step (e.g., act or task) S200 of forming the base oxide layer on the base mask substrate may include forming a base oxide layer BOXL covering the base mask substrate BSS. The base oxide layer BOXL may be for forming the oxide layer OXL, and may be etched to form the oxide layer OXL. The base oxide layer BOXL may include a same material as the oxide layer OXL.

The base oxide layer BOXL may completely cover each of top, bottom, and side surfaces of the base mask substrate BSS. For example, in one or more embodiments, the base oxide layer BOXL may be in contact with each of the top, bottom, and side surfaces of the base mask substrate BSS. At least a portion of the base oxide layer BOXL may be arranged in the groove GRV. For example, at least a portion of the base oxide layer BOXL may cover the groove GRV. For example, at least a portion of the base oxide layer BOXL may be in contact with bottom and side surfaces of the groove GRV.

The base oxide layer BOXL may be formed by thermal oxidation of the surface of the base mask substrate BSS, or may be deposited by Chemical Vapor Deposition. However, embodiments of the present disclosure are not limited thereto.

Referring to FIG. 9, step (e.g., act or task) S250 of forming the alignment mark in the groove of the base mask substrate may include forming the alignment mark ALM on the base oxide layer BOXL arranged over the groove GRV. The alignment mark ALM may be formed in a region overlapping with the groove GRV. The alignment mark ALM may be in contact with the base oxide layer BOXL arranged in the region overlapping with the groove GRV.

According to one or more embodiments, a side surface of the alignment mark ALM may be in contact with the base oxide layer BOXL. However, embodiments of the present disclosure are not limited thereto. According to one or more embodiments, the side surface of the alignment mark ALM may be spaced and/or apart (e.g., spaced apart or separated) from the base oxide layer BOXL.

The alignment mark ALM may be deposited only in the groove GRV region. However, embodiments of the present disclosure are not limited thereto. According to one or more embodiments, after a photoresist exposing the groove GRV region is formed, a metal layer may be deposited, and the photoresist may be removed to form the alignment mark ALM. In one or more embodiments, the metal layer may be deposited on the base oxide layer BOXL, and the metal layer arranged in a region other than the groove GRV region may be etched to form the alignment mark ALM.

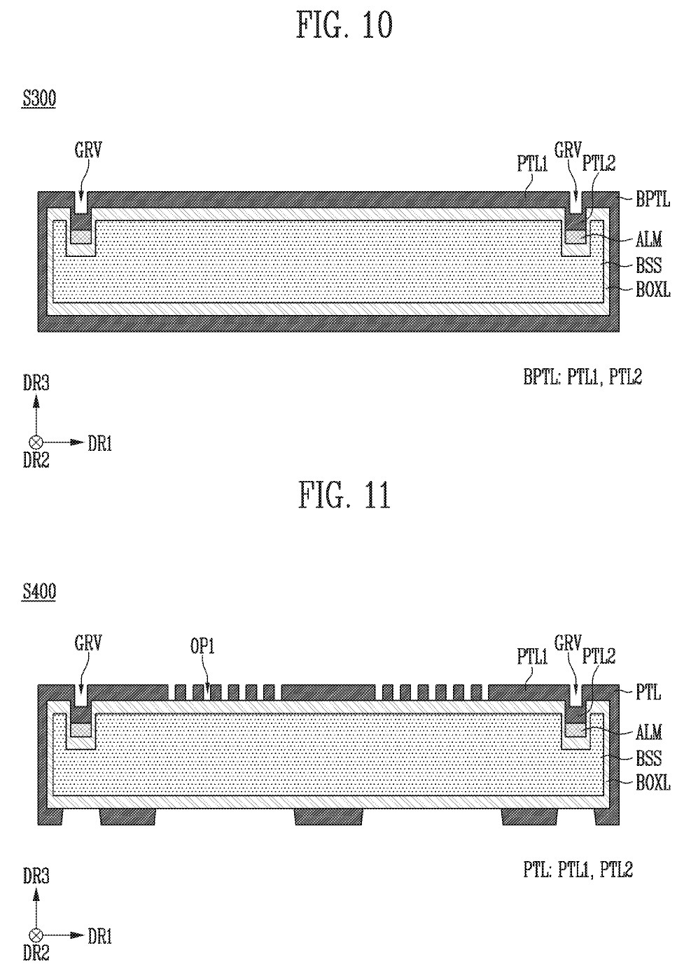

Referring to FIG. 10, step (e.g., act or task) S300 of forming the base pattern layer in on the base oxide layer may include forming a base pattern layer BPTL covering the base oxide layer BOXL and the alignment mark ALM. According to a method of manufacturing the mask MSK according to the first embodiment, step (e.g., act or task) S300 of forming the base pattern layer on the base oxide layer may be performed after step (e.g., act or task) S250 of forming the alignment mark in the groove of the base mask substrate. For example, in one or more embodiments, the alignment mark ALM may be formed before the base pattern layer BPTL is formed.

The base pattern layer BPTL may be etched to form the pattern layer PTL. The base pattern layer BPTL may include a same material as the pattern layer PTL.

The base pattern layer BPTL may include the first pattern layer PTL1 arranged on the base oxide layer BOXL and the second pattern layer PTL2 arranged within the groove GRV. For example, the first pattern layer PTL1 may be part of the base pattern layer BPTL arranged higher than the base oxide layer BOXL in the third direction DR3. For example, the second pattern layer PTL2 may be part of the base pattern layer BPTL arranged lower than the base oxide layer BOXL arranged on a top surface of the base mask substrate BSS in the third direction DR3 and arranged within the groove GRV.

Referring to FIG. 11, step (e.g., act or task) S400 of etching the base pattern layer may include etching the base pattern layer BPTL to form the pattern layer openings OP1 through which the deposition material passes. Step S400 of etching the base pattern layer may further include etching a portion of the base pattern layer BPTL arranged on a bottom surface of the base mask substrate BSS. For example, the base pattern layer BPTL arranged on the bottom surface of the base mask substrate BSS and arranged in a region overlapping with the groove GRV and the pattern layer openings OP1 may be etched. The base pattern layer BPTL may be etched to form the pattern layer PTL.

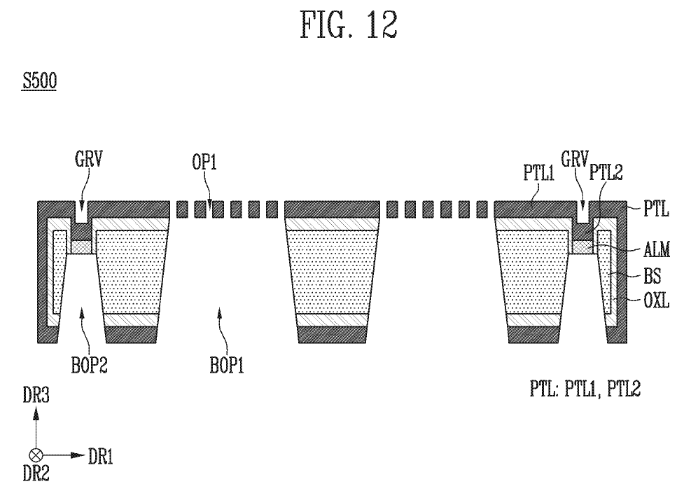

Referring to FIG. 12, step (e.g., act or task) S500 of etching the base oxide layer and the base mask substrate may include etching the base oxide layer BOXL arranged on the bottom surface of the base mask substrate BSS and arranged in a region overlapping with the groove GRV and the pattern layer openings OP1. Step S500 of etching the base oxide layer and the base mask substrate may include etching the base mask substrate BSS arranged in the region overlapping with the groove GRV and the pattern layer openings OP1. Step S500 of etching the base oxide layer and the base mask substrate may include etching the base oxide layer BOXL arranged in the groove GRV region and etching the base oxide layer BOXL arranged on the top surface of the base mask substrate BSS and in the region overlapping with the pattern layer openings OP1.

The base oxide layer BOXL may be etched to form the oxide layer OXL, and the base mask substrate BSS may be etched to form the mask substrate BS. The base mask substrate BSS may be etched to form the first substrate opening BOP1 overlapping with the pattern layer openings OP1, and the second substrate opening BOP2 overlapping with the groove GRV may be formed.

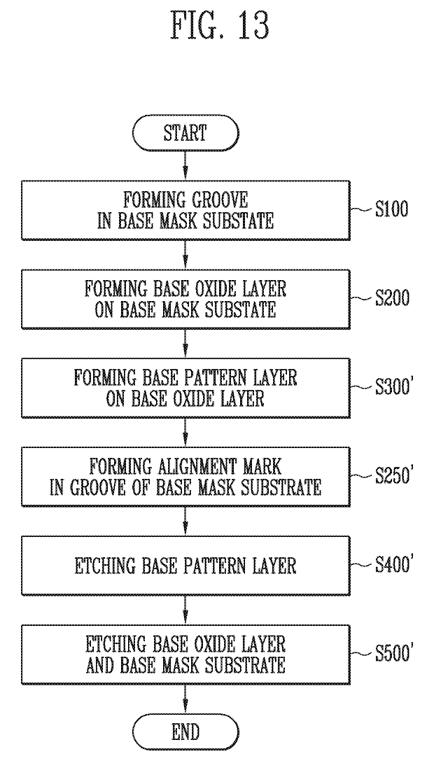

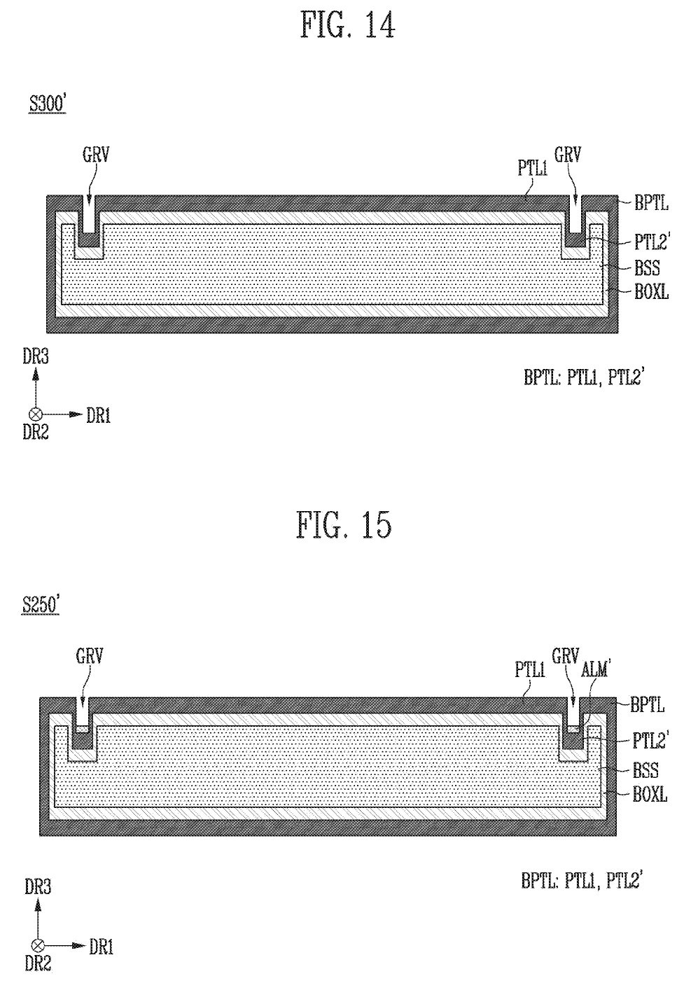

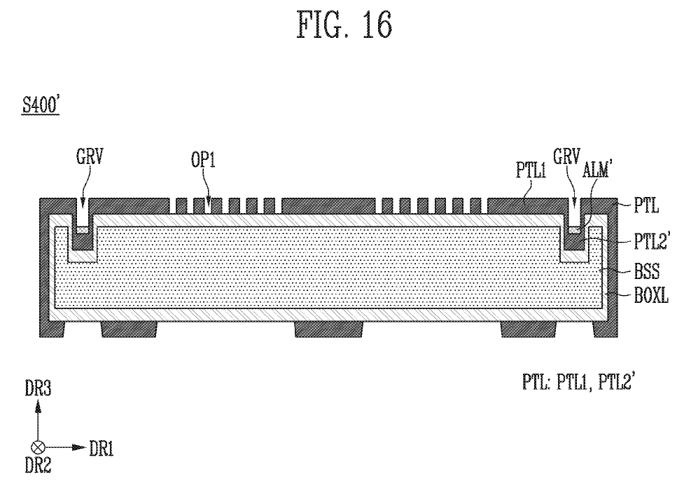

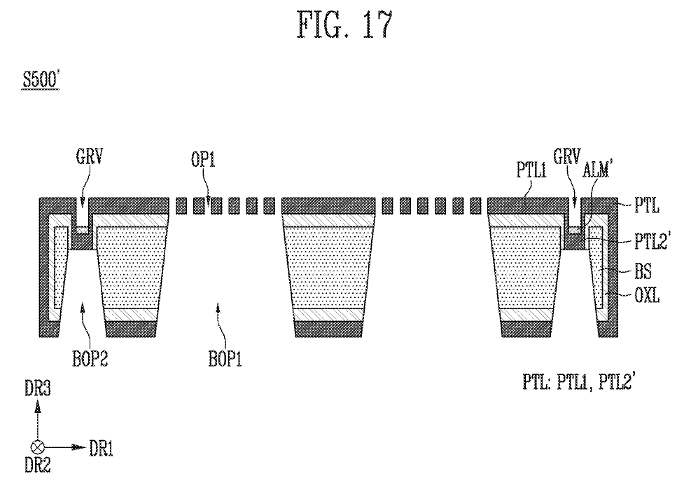

Hereinafter, a method of manufacturing the deposition mask MSK’ will be described with reference to FIGS. 13 - 17. FIG. 13 is a flowchart illustrating a method of manufacturing the deposition mask MSK’ of FIG. 4 according to one or more embodiments of the present disclosure. FIGS. 14 - 17 are schematic cross-sectional views illustrating the method of manufacturing the deposition mask MSK’ of FIG. 13 according to one or more embodiments. Descriptions of content overlapping with the foregoing will be briefly provided or omitted.

Referring to FIG. 13, the method of manufacturing deposition mask MSK’ may include step (e.g., act or task) S100 of forming a groove in a base mask substrate, step (e.g., act or task) S200 of forming a base oxide layer on the base mask substrate, step (e.g., act or task) S300’ of forming a base pattern layer on the base oxide layer, step (e.g., act or task) S250’ of forming an alignment mark in the groove in the base mask substrate, step (e.g., act or task) S400’ of etching the base pattern layer, and step (e.g., act or task) S500’ of etching the base oxide layer and the base mask substrate.

Referring to FIG. 14, step (e.g., act or task) S300’ of forming the base pattern layer on the base oxide layer may include forming the base pattern layer BPTL covering the base oxide layer BOXL. According to the method of manufacturing the mask MSK’ according to the second embodiment, step (e.g., act or task) S300’ of forming the base pattern layer on the base oxide layer may be performed prior to step (e.g., act or task) S250’ of forming the alignment mark in the groove of the base mask substrate. For example, the alignment mark ALM’ may be formed after the base pattern layer BPTL is formed.

In the region overlapping with the groove GRV, a bottom surface of the second pattern layer PTL2’ may be in contact with a top surface of the base oxide layer BOXL.

Referring to FIG. 15, step (e.g., act or task) S250’ of forming the alignment mark in the groove of the base mask substrate may include forming the alignment mark ALM’ on the second pattern layer PTL2’ arranged in the groove GRV. The alignment mark ALM’ may be formed in the region overlapping with the groove GRV. The alignment mark ALM’ may be in contact with the second pattern layer PTL2’ arranged in the region overlapping with the groove GRV.

According to one or more embodiments, a side surface of the alignment mark ALM’ may be in contact with the base pattern layer BPTL. However, embodiments of the present disclosure are not limited thereto. According to one or more embodiments, the side surface of the alignment mark ALM may be spaced and/or apart (e.g., spaced apart or separated) from the base pattern layer BPTL.

Referring to FIG. 16, step (e.g., act or task) S400’ of etching the base pattern layer may include etching the base pattern layer BPTL to form the pattern layer openings OP1 through which the deposition material passes. Step S400’ of etching the base pattern layer may further include etching a portion of the base pattern layer BPTL arranged on a bottom surface of the base mask substrate BSS. For example, the base pattern layer BPTL arranged on the bottom surface of the base mask substrate BSS and arranged in the region overlapping with the groove GRV and the pattern layer openings OP1 may be etched. The base pattern layer BPTL may be etched to form the pattern layer PTL.

Referring to FIG. 17, step (e.g., act or task) S500’ of etching the base oxide layer and the base mask substrate may include etching the base oxide layer BOXL arranged on the bottom surface of the base mask substrate BSS and arranged in the region overlapping with the groove GRV and the pattern layer openings OP1. Step S500’ of etching the base oxide layer and the base mask substrate may include etching the base mask substrate BSS arranged in the region overlapping with the groove GRV and the pattern layer openings OP1. Step S500’ of etching the base oxide layer and the base mask substrate may include etching the base oxide layer BOXL arranged in the groove GRV region and etching the base oxide layer BOXL arranged on a top surface of the base mask substrate BSS and in the region overlapping with the pattern layer openings OP1.

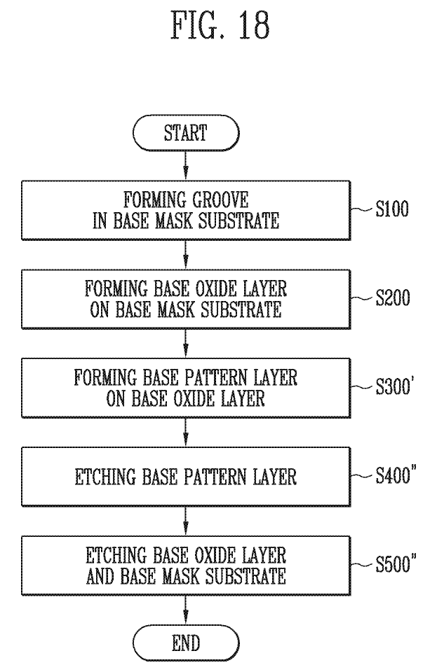

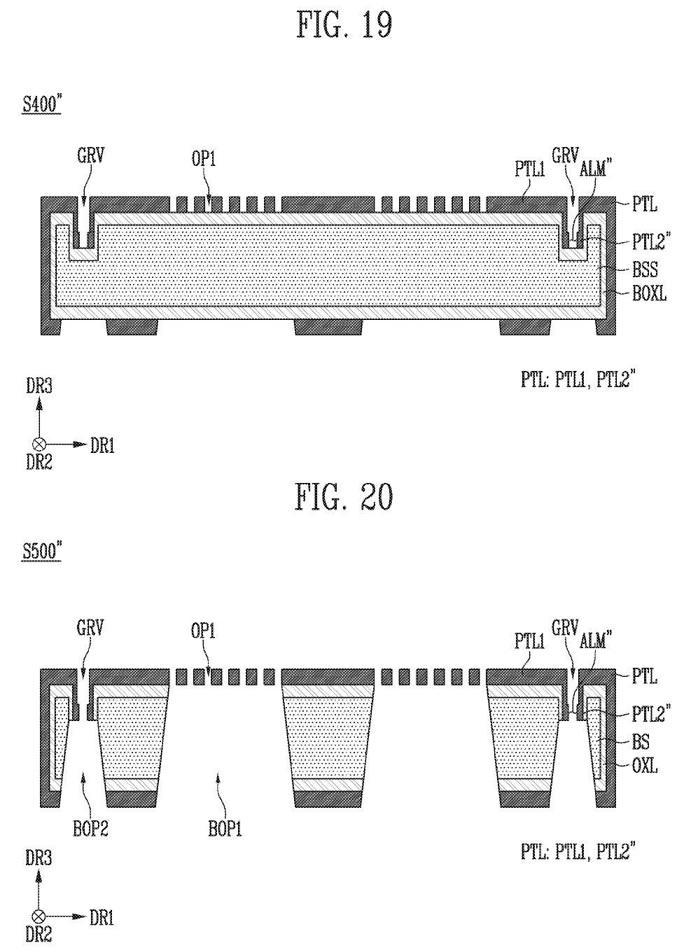

Hereinafter, a method of manufacturing the deposition mask MSK” will be described with reference to FIGS. 18 - 20. FIG. 18 is a flowchart illustrating a method of manufacturing the deposition mask MSK” of FIG. 5 according to one or more embodiments of the present disclosure. FIGS. 19 and 20 are schematic cross-sectional views of the method of manufacturing the deposition mask MSK” of FIG. 18 according to one or more embodiments. Descriptions of content overlapping with the foregoing will be briefly provided or omitted.

Referring to FIG. 18, the method of manufacturing the deposition mask MSK” may include step (e.g., act or task) S100 of forming a groove on a base mask substrate, step (e.g., act or task) S200 of forming a base oxide layer on the base mask substrate, step (e.g., act or task) S300’ of forming a base pattern layer on the base oxide layer, step (e.g., act or task) S400” of etching the base pattern layer, and step (e.g., act or task) S500” of etching the base oxide layer and the base mask substrate.

Referring to FIG. 19, step (e.g., act or task) S400” of etching the base pattern layer may include etching the base pattern layer BPTL to form the pattern layer openings OP1 through which the deposition material passes. Step S400” of etching the base pattern layer may further include etching a portion of the base pattern layer BPTL arranged on a bottom surface of the base mask substrate BSS. For example, the base pattern layer BPTL arranged on the bottom surface of the base mask substrate BSS and arranged in a region overlapping with the groove GRV and the pattern layer openings OP1 may be etched. The base pattern layer BPTL may be etched to form the pattern layer PTL.

Step S400” of etching the base pattern layer may further include etching the second pattern layer PTL2 to form an alignment opening corresponding to the alignment mark ALM”.

Referring to FIG. 20, step (e.g., act or task) S500” of etching the base oxide layer and the base mask substrate may include etching the base oxide layer BOXL arranged on a bottom surface of the base mask substrate BSS and arranged in the overlapping with the groove GRV and the pattern layer openings OP1. Step S500” of etching the base oxide layer and the base mask substrate may include etching the base mask substrate BSS arranged in the region overlapping with the groove GRV and the pattern layer openings OP1. Step S500” of etching the base oxide layer and the base mask substrate may include etching the base oxide layer BOXL arranged in the groove GRV region and etching the base oxide layer BOXL arranged on a top surface of the base mask substrate BSS and in the region overlapping with the pattern layer openings OP1.

Hereinafter, with reference to FIGS. 21 - 24, the display device DD will be described. The display device DD according to one or more embodiments of the present disclosure may be manufactured using the deposition mask MSK and the deposition apparatus EB (or the deposition source ES described above).

FIG. 21 is a schematic plan view illustrating a display device DD according to one or more embodiments of the present disclosure.

Referring to FIG. 21, the display device DD (or a display panel) may include a display area DA and a non-display area NDA. The display device DD displays an image through the display area DA. The non-display area NDA is arranged around the periphery of the display area DA.

The display device DD may include a substrate SUB, sub-pixels SP, and/or pads PD.

The sub-pixels SP are arranged in the display area DA on the substrate SUB. In one or more embodiments, the sub-pixels SP may be arranged in a matrix format along a first direction DR1 and a second direction DR2 intersecting the first direction DR1. However, embodiments of the present disclosure are not limited thereto. For example, in one or more embodiments, the sub-pixels SP may be arranged in a zigzag pattern along the first direction DR1 and the second direction DR2. For example, in one or more embodiments, the sub-pixels SP may be arranged in a PenTile^{®} configuration in which the sub-pixels SP are arranged in a rhombic shape. PenTile^{®} is a duly registered trademark of Samsung Display Co., Ltd. The first direction DR1 may be a row direction and the second direction DR2 may be a column direction. Two or more of the sub-pixels SP may constitute a single pixel PXL.

Components for controlling the sub-pixels SP may be arranged in the non-display area NDA on the substrate SUB. For example, in one or more embodiments, wiring lines connected to the sub-pixels SP, such as gate lines and data lines, may be arranged in the non-display area NDA.

Pads PD are arranged in the non-display area NDA on the substrate SUB. The pads PD may be electrically connected to the sub pixels SP via the wiring lines. For example, the pads PD may be connected to the sub-pixels SP via the data lines.

Voltages and signals for operations of the components included in the display device DD may be provided through the pads PD from a driver integrated circuit. For example, data lines may be connected to the driver integrated circuit via the pads PD. For example, power voltages may be received from the driver integrated circuit through the pads PD.

In one or more embodiments, a circuit board may be electrically connected to the pads PD using a conductive adhesive member, such as an anisotropic conductive film. The circuit board may be a flexible circuit board or a flexible film having a flexible material. The driver integrated circuit may be mounted on the circuit board and electrically connected to the pads PD.

In one or more embodiments, the display area DA may have one or more suitable shapes. The display area DA may have a shape of a closed loop including straight and/or curved sides. For example, in one or more embodiments, the display area DA may have the shape of a polygon, a circle, a semicircle, an ellipse, and/or the like.

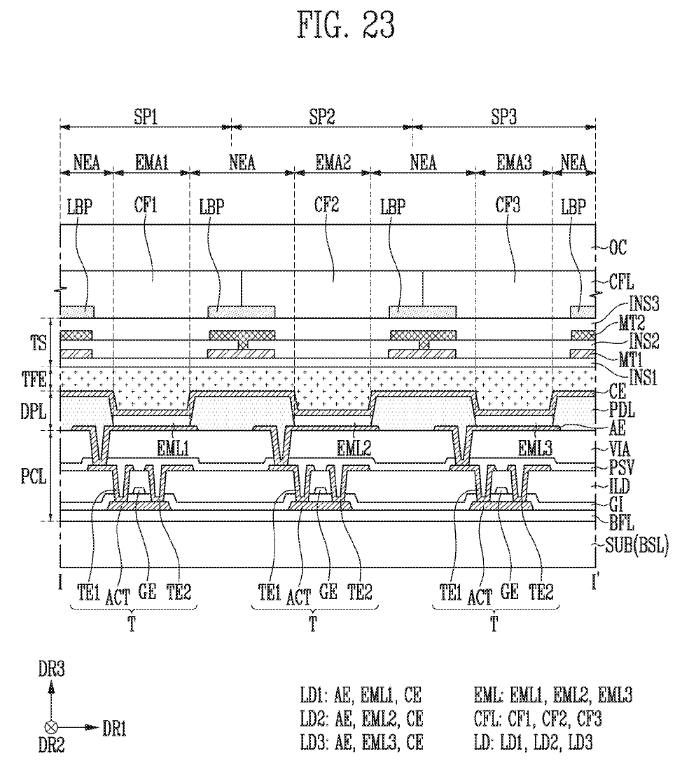

In one or more embodiments, the display device DD may have a flat display surface. In one or more embodiments, the display device DD may have a display surface which is at least partially rounded. In one or more embodiments, the display device DD may be bendable, foldable, or rollable. The display device DD and/or a base layer BSL (see FIG. 23) may include materials having flexible properties.

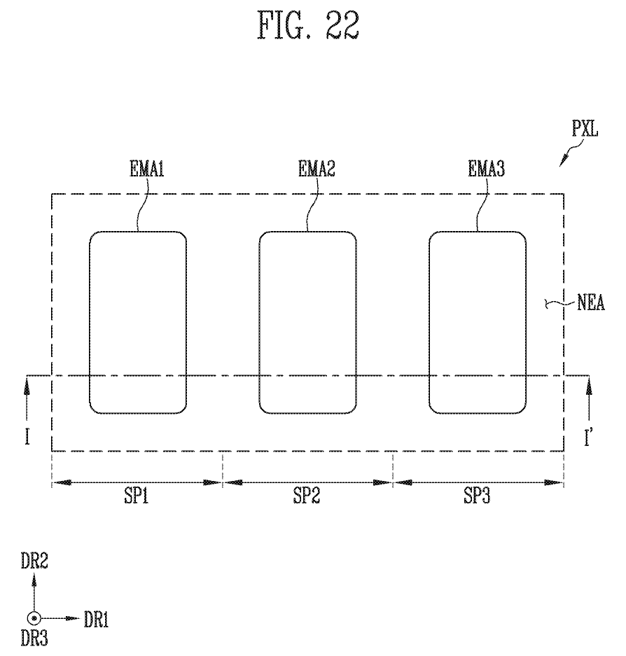

FIG. 22 is a schematic top view illustrating sub-pixels according to one or more embodiments of the present disclosure.

Referring to FIG. 22, in one or more embodiments, a pixel PXL may include first to third sub-pixels SP1 to SP3 arranged in the first direction DR1. The first sub-pixel SP1 may include a first emission area EMA1 and a non-emission area NEA around the first emission area EMA1. The second sub-pixel SP2 may include a second emission area EMA2 and the non-emission area NEA around the second emission area EMA2. The third sub-pixel SP3 may include a third emission area EMA3 and the non-emission area NEA around the third emission area EMA3.

The first emission area EMA1 may be an area where light is emitted from a first light emitting layer EML1 of the first sub-pixel SP1 (see FIG. 23). The second emission area EMA2 may be an area where light is emitted from a second light emitting layer EML2 of the second sub-pixel SP2 (see FIG. 23). The third emission area EMA3 may be an area where light is emitted from a third light emitting layer EML3 of the third sub-pixel SP3 (see FIG. 23).

FIG. 23 is a schematic cross-sectional view taken along the line I-I’ line of FIG. 22 according to one or more embodiments of the present disclosure.

Referring to FIG. 23, the first, second, and third sub-pixels SP1, SP2, and SP3 may include the emission areas EMA1, EMA2, and EMA3, respectively, and the non-emission areas NEA may be located between the emission areas EMA1, EMA2, and EMA3 of the first, second, and third sub-pixels SP1 to SP3.

Each of the first to third sub-pixels SP1 to SP3 may include a pixel circuit layer PCL, a display device layer DPL, and/or a thin-film encapsulation layer TFE arranged sequentially on a base layer BSL (or the substrate SUB).

The base layer BSL may form a base surface. In one or more embodiments, the base layer BSL may include a transparent insulating material to allow transmission of light. The base layer BSL may be a rigid substrate or a flexible substrate. The rigid substrate may be one selected from among, for example, a glass substrate, a quartz substrate, a glass-ceramic substrate, and a crystalline glass substrate. The flexible substrate may be one of a film substrate including a polymeric organic material and a plastic substrate. For example, the flexible substrate may be at least one selected from among polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate, but embodiments of the present disclosure are not limited thereto. For example, in one or more embodiments, the base layer BSL may be a substrate including silicon. According to one or more embodiments, the display device DD may be an organic light-emitting diode (OLED) on silicon (OLEDoS) display device including a display panel formed on a silicon substrate.

The pixel circuit layer PCL may include a buffer layer BFL, a gate insulating layer GI, an interlayer insulating layer ILD, a passivation layer PSV, and/or a via layer VIA stacked sequentially on the base layer BSL along a third direction DR3 (e.g., a thickness direction).

The buffer layer BFL may be an inorganic insulating layer including an inorganic material. The buffer layer BFL may include at least one selected from among silicon nitride (SiNₓ), silicon oxide (SiOₓ), silicon oxynitride (SiOₓN_{y}), and metal oxides such as aluminum oxide (AlOₓ)_{.} In one or more embodiments, the buffer layer BFL may be provided as a single layer, but may also be provided as a multilayer structure of at least two layers. If (e.g., when) the buffer layer BFL is provided as multiple layers, each layer may be formed from a same material or different materials. In one or more embodiments, the buffer layer BFL may not be provided depending on the material and process conditions of the base layer BSL.

A transistor T may be arranged on the buffer layer BFL. The transistor T may include an active pattern ACT, a gate electrode GE, a first transistor electrode TE1, and/or a second transistor electrode TE2.

The active pattern ACT may be arranged on the buffer layer BFL. In one or more embodiments, the active pattern ACT may include a polysilicon semiconductor. For example, the active pattern ACT may be formed through a low temperature polysilicon process. However, embodiments of the present disclosure are not limited thereto, for example, in one or more embodiments, the active pattern ACT may include an oxide semiconductor, a metal oxide semiconductor, and/or the like.

The active pattern ACT may include a channel region, a first contact region in contact with one end of the channel region, and a second contact region in contact with the other end of the channel region. Each of the channel region, the first contact region, and the second contact region may include a semiconductor layer which is undoped or doped with impurities. For example, each of the first contact region and the second contact region may include a semiconductor layer doped with impurities, and the channel region may include a semiconductor layer which is not doped with impurities. As the impurities, in one or more embodiments, P-type (kind) impurities may be used. However, embodiments of the present disclosure are not limited thereto. One of the first and second contact regions may be a source region, and the other may be a drain region.

The gate insulating layer GI may be arranged on the active pattern ACT. The gate insulating layer GI may be an inorganic layer (or an inorganic insulating layer) including an inorganic material. For example, in one or more embodiments, the gate insulating layer GI may include at least one selected from among silicon nitride (SiNₓ), silicon oxide (SiOₓ), silicon oxynitride (SiOₓN_{y}), and a metal oxide such as aluminum oxide (AlOₓ)_{.} However, the material of the gate insulating layer GI is not limited to the embodiments described above. In one or more embodiments, the gate insulating layer GI may include an organic layer (or an organic insulating layer) including an organic material. The gate insulating layer GI may be provided as a single layer, but may also be provided as a multilayer structure including at least two layers.

The gate electrode GE may be arranged on the gate insulating layer GI. The gate electrode GE may overlap with the channel region of the active pattern ACT. The gate electrode GE may be formed as a single layer of a material selected from the group consisting of copper (Cu), molybdenum (Mo), tungsten (W), aluminum neodymium (AlNd), titanium (Ti), aluminum (Al), silver (Ag), and an alloy thereof, or a mixture thereof, or may be formed as a double-layer or multilayer structure of low resistivity materials such as molybdenum (Mo), titanium (Ti), copper (Cu), aluminum (Al), and silver (Ag) so as to reduce wiring resistance.

The interlayer insulating layer ILD may be arranged on the gate electrode GE. The interlayer insulating layer ILD may include a same material as the gate insulating layer GI or may include at least one material selected from among the materials exemplified as the components of the gate insulating layer GI.

The first transistor electrode TE1 and the second transistor electrode TE2 may be arranged on the interlayer insulating layer ILD. The first transistor electrode TE1 of the transistor T may contact the first contact region of the active pattern ACT through a contact hole through the interlayer insulating layer ILD and the gate insulating layer GI. If (e.g., when) the first contact region is a source region, the first transistor electrode TE1 may be a first source electrode.

The second transistor electrode TE2 of the transistor T may contact the second contact region of the other end of the active pattern ACT through a contact hole through the interlayer insulating layer ILD and the gate insulating layer GI. If (e.g., when) the second contact region is a drain region, the second transistor electrode TE2 may be a second drain electrode.

The first transistor electrode TE1 and the second transistor electrode TE2 may each include a same material as the gate electrode GE, or may include at least one material selected from among the materials exemplified as the constituent materials of the gate electrode GE.

The passivation layer PSV may be arranged on the first transistor electrode TE1 and the second transistor electrode TE2. The passivation layer PSV (e.g., a protective layer) may be an inorganic layer (or an inorganic insulating layer) including an inorganic material or an organic layer (or an organic insulating layer) including an organic material. The inorganic layer may include at least one selected from among silicon oxide (SiOₓ), silicon nitride (SiNx), silicon oxynitride (SiOₓN_{y}), and a metal oxide, such as aluminum oxide (AlOₓ)_{.} The organic layer may include at least one selected from among a polyacrylate resin, an epoxy resin, a phenolic resin, a polyamide resin, a polyimide resin, an unsaturated polyester resin, a polyphenylene ether resin, a polyphenylene sulfide resin, and a benzocyclobutene resin.

According to one or more embodiments, the passivation layer PSV may include, but is not limited to, a same material as the interlayer insulating layer ILD. In one or more embodiments, the passivation layer PSV may be provided as a single layer. In one or more embodiments, the passivation layer PSV may be provided as a multilayer structure including at least two layers.

The via layer VIA may be arranged on top of the passivation layer PSV. The via layer VIA may include a same material as the passivation layer PSV or at least one material selected from among the materials exemplified as the components of the passivation layer PSV. According to one or more embodiments, the via layer VIA may be an organic layer including an organic material.

The display device layer DPL may be arranged on top of the pixel circuit layer PCL. The display device layer DPL may include a light emitting element LD (i.e., LD1, LD2, LD3) which emits light. The first to third sub-pixels SP1 to SP3 may include first to third light emitting elements LD1 to LD3, respectively.

The first light emitting element LD1 may include an anode electrode AE, a first light emitting layer EML1, and a cathode electrode CE. The second light emitting element LD2 may include an anode electrode AE, a second light emitting layer EML2, and the cathode electrode CE. The third light emitting element LD3 may include an anode electrode AE, a third light emitting layer EML3, and the cathode electrode CE. In one or more embodiments, the first to third light emitting elements LD1 to LD3 may each be a top-emission organic light emitting element.

In one or more embodiments, the anode electrodes AE of the sub-pixels SP may be arranged in the emission areas EMA1, EMA2, and EMA3 and may be spaced and/or apart (e.g., spaced apart or separated) from one another. In one or more embodiments, the anode electrode AE of each sub-pixel SP may be electrically connected to the first transistor electrode TE1 of the transistor T of each sub-pixel SP through a contact hole through the via layer VIA and the passivation layer PSV.

A pixel defining layer PDL (or a bank) may be arranged on the anode electrode AE. The pixel defining layer PDL may define or divide the emission area EMA1, EMA2, or EMA3 of each sub-pixel SP. The pixel defining layer PDL may include an opening which partially exposes the anode electrode AE of each sub-pixel SP.

The pixel defining layer PDL may be an organic insulating layer including an organic material. The organic material may include an acryl resin, an epoxy resin, a phenolic resin, a polyamide resin, a polyimide resin, and/or the like. However, embodiments of the present disclosure are not limited thereto, for example, in one or more embodiments, the pixel defining layer PDL may be an inorganic insulating layer made of an inorganic material.

In one or more embodiments, the pixel defining layer PDL may include a light absorbing material or may be coated with a light absorber to absorb light from an external source. For example, in one or more embodiments, the pixel defining layer PDL may include a carbon-based black pigment. However, embodiments of the present disclosure are not limited thereto, for example, in one or more embodiments, the pixel defining layer PDL may include an opaque metal material having high light absorptivity, such as chromium (Cr), an alloy (MoTi) of molybdenum (Mo) and titanium (Ti), tungsten (W), vanadium (V), niobium (Nb), tantalum (Ta), manganese (Mn), cobalt (Co), or nickel (Ni).

A light emitting layer EML of each sub-pixel SP may be arranged on the anode electrode AE exposed by the pixel defining layer PDL. The cathode electrode CE may be arranged on the light emitting layer EML. The cathode electrode CE may be arranged across the first to third sub-pixels SP1 to SP3. In one or more embodiments, the cathode electrodes CE may be provided as a common electrode, but embodiments of the present disclosure are not limited thereto.

The cathode electrode CE may a metal layer formed of, such as, silver (Ag), magnesium (Mg), aluminum (Al), platinum (Pt), palladium (Pd), gold (Au), nickel (Ni), neodymium (Nd), iridium (Ir), chromium (Cr), or an alloy thereof, and/or a transparent conductive layer formed of, such as, indium tin oxide (ITO), indium zinc oxide (IZO), zinc oxide (ZnO), or indium tin zinc oxide (ITZO). According to one or more embodiments, the cathode electrode CE may have a multilayer structure of two or more layers including a metal thin layer, for example, a triple layer of ITO/Ag/ITO.

The thin-film encapsulation layer TFE may be arranged on the display device layer DPL. The thin-film encapsulation layer TFE may have a single-layer structure or a multi-layer structure. The thin-film encapsulation layer TFE may include an insulating layer covering the light emitting element LD (i.e., LD1, LD2, and LD3). In one or more embodiments, the thin-film encapsulation layer TFE may include at least one inorganic layer and at least one organic layer. For example, in one or more embodiments, the thin-film encapsulation layer TFE may have a multilayer structure of inorganic layer and organic layer alternating with each other. In one or more embodiments, the thin-film encapsulation layer TFE may include a first inorganic layer, an organic layer arranged on the first inorganic layer, and a second inorganic layer arranged on the organic layer.

In one or more embodiments, a sensing layer TS may be arranged on the thin-film encapsulation layer TFE. The sensing layer TS may include a first insulating layer INS1, a first conductive layer MT1, a second insulating layer INS2, a second conductive layer MT2, and/or a third insulating layer INS3.

The first insulating layer INS1 may be arranged on the thin-film encapsulation layer TFE. In one or more embodiments, the first insulating layer INS1 may be an inorganic insulating layer including an inorganic material. The inorganic insulating layer may include an inorganic insulating material such as silicon oxide (SiOₓ), silicon nitride (SiNₓ), silicon oxynitride (SiOₓN_{y}), aluminum oxide (AlₓO_{y}), titanium oxide (TiOₓ),tantalum oxide (TaₓO_{y}), hafnium oxide (HfOₓ), zinc oxide (ZnOₓ), and/or the like. According to one or more embodiments, the first insulating layer INS1 may not be provided or may be configured as a top layer of the thin-film encapsulation layer TFE.

The first conductive layer MT1 may be arranged on top of the first insulating layer INS1. The first conductive layer MT1 may be partially opened so as not to overlap with the light emitting element LD of each sub-pixel SP. In one or more embodiments, the first conductive layer MT1 may be arranged to overlap with the non-emission areas NEA around the emission areas EMA1, EMA2, and EMA3.

The first conductive layer MT1 may include a metal layer or a transparent conductive layer. For example, the metal layer may include molybdenum, titanium, copper, aluminum, and/or an alloy thereof. The transparent conductive layer may include, but is not limited to, at least one selected from among indium tin oxide (ITO), indium zinc oxide (IZO), zinc oxide (ZnO), indium tin zinc oxide (ITZO), poly(3,4-ethylenedioxythiophene) PEDOT, and metal nanowires. The first conductive layer MT1 may form a connecting electrode connecting sensing electrodes.

The second insulating layer INS2 may be arranged on top of the first conductive layer MT1. The second insulating layer INS2 may include a same material as the first insulating layer INS1 as described above, or may include at least one material selected from among the materials exemplified as the components of the first insulating layer INS1.

The second conductive layer MT2 may be arranged on the second insulating layer INS2. The second conductive layer MT2 may be partially opened so as not to overlap with the light emitting element LD (LD1, LD2, or LD3) of each sub-pixel SP. In one or more embodiments, the second conductive layer MT2 may be arranged to overlap with the non-emission areas NEA around the emission areas EMA1, EMA2, and EMA3.

The second conductive layer MT2 may include a same material as the first conductive layer MT1 as described above, or may include at least one material selected from among the materials exemplified as the components of the first conductive layer MT1.

The second conductive layer MT2 may be electrically connected to the first conductive layer MT1 via a contact hole through the second insulating layer INS2. The second conductive layer MT2 may include sensing electrodes.

The third insulating layer INS3 may be arranged on the second conductive layer MT2. In one or more embodiments, the third insulating layer INS3 may be an organic insulating layer including an organic material. However, embodiments of the present disclosure are not limited thereto, for example, according to one or more embodiments, the third insulating layer INS3 may be an inorganic layer, or may have a structure of alternating organic and inorganic layers stacked.

A light-blocking layer LBP may be arranged on the display element layer DPL, the thin-film encapsulation layer TFE, and/or the sensing layer TS. The light-blocking layer LBP may include an opening which overlaps with the light emitting element LD (i.e., LD1, LD2, and LD3). In one or more embodiments, the light-blocking layer LBP may be arranged to overlap with the non-emission area NEA around the emission areas EMA1, EMA2, and EMA3.

The light-blocking layer LBP may include a light-blocking material to prevent or reduce light leakage and poor coloration. In one or more embodiments, the light-blocking layer LBP may include, but is not limited to, a black matrix. According to one or more embodiments, the light-blocking layer LBP may include carbon black (CB) and/or titanium black (TiBK).

A color filter layer CFL may be arranged on the light-blocking layer LBP. The color filter layer CFL may include color filters CF1 to CF3 corresponding to colors of the sub-pixels SP. By arranging the color filters CF1 to CF3 corresponding to the colors of the first to third sub-pixels SP1 to SP3, a full-color image may be displayed.

The color filter layer CFL may include the first color filter CF1 arranged in the first sub-pixel SP1 to selectively transmit light emitted by the first sub-pixel SP1, the second color filter CF2 arranged in the second sub-pixel SP2 to selectively transmit light emitted by the second sub-pixel SP2, and the third color filter CF3 arranged in the third sub-pixel SP3 to selectively transmit light emitted by the third sub-pixel SP3.

According to one or more embodiments, the first color filter CF1, the second color filter CF2, and the third color filter CF3 may be, but are not limited to, a red color filter, a green color filter, and a blue color filter, respectively.

The first color filter CF1 may include a color filter material which selectively transmits light of a first color (or red). For example, if (e.g., when) the first sub-pixel SP1 is a red sub-pixel, the first color filter CF1 may include a red color filter material.

The second color filter CF2 may include a color filter material which selectively transmits light of a second color (or green). For example, if (e.g., when) the second sub-pixel SP2 is a green sub-pixel, the second color filter CF2 may include a green color filter material.

The third color filter CF3 may include a color filter material which selectively transmits light of a third color (or blue). For example, if (e.g., when) the third sub-pixel SP3 is a blue sub-pixel, the third color filter CF3 may include a blue color filter material.

An overcoat layer OC may be provided on the color filter layer CFL. The overcoat layer OC may include a variety of materials suitable for protecting the lower layers from foreign matter such as dust, moisture, and/or the like. For example, in one or more embodiments, the overcoat layer OC may include at least one of an inorganic insulating layer or an organic insulating layer. For example, in one or more embodiments, the overcoat layer OC may include epoxy, but embodiments of the present disclosure are not limited thereto.

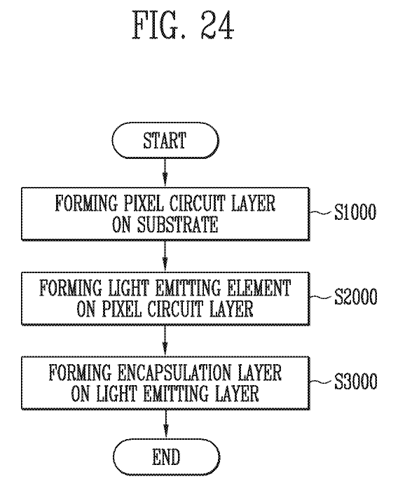

Hereinafter, with reference to FIG. 24, a method of manufacturing the display device DD will be described.

FIG. 24 is a flowchart illustrating a method of manufacturing the display device DD according to one or more embodiments of the present disclosure. The method of manufacturing the display device DD according to one or more embodiments of the present disclosure may be a method of manufacturing the display device DD using the deposition mask MSK and the deposition apparatus EB (or the deposition source ES) as described above.

Referring to FIG. 24, the method of manufacturing the display device DD may include step (e.g., act or task) S1000 of forming a pixel circuit layer on a substrate, step (e.g., act or task) S2000 of forming a light-emitting element on the pixel circuit layer, and step (e.g., act or task) S3000 of forming an encapsulation layer on the light-emitting element.

Referring to FIGS. 23 and 24, in step (e.g., act or task) S1000 of forming the pixel circuit layer on the substrate, circuit elements on the substrate SUB may be patterned, and the pixel circuit layer PCL may be provided.

According to one or more embodiments, a conductive layer and an insulating layer on the substrate SUB may be formed based on a general process of manufacturing a semiconductor device. For example, the conductive layer or the insulating layer on the substrate may be formed by a photolithography process, may be etched by one or more suitable methods (wet etching, dry etching, and/or the like), and may be deposited by one or more suitable methods (sputtering, chemical vapor deposition, and/or the like). Embodiments of the present disclosure are not limited to any particular example.

In step (e.g., act or task) S1000 of forming the pixel circuit layer on the substrate, transistors T may be patterned on the substrate SUB.

In step (e.g., act or task) S2000 of forming the light emitting element on the pixel circuit layer, the anode electrode AE, the first to third light emitting layers EML1 to EML3, and the cathode electrode CE may be formed to form the first to third light emitting elements LD1 to LD3.

In step (e.g., act or task) S2000 of forming the light emitting element on the pixel circuit layer, the anode electrodes AE may be patterned, and the pixel defining layer PDL overlapping with the anode electrodes AE may be patterned.

Subsequently, a process of depositing the first to third light emitting layers EML1 to EML3 on corresponding anode electrodes AE may be performed. The first to third light emitting layers EML1 to EML3 may be deposited using the deposition mask MSK and the deposition apparatus EB as described above. For example, the materials for forming the first to third light emitting layers EML1 to EML3 may be arranged on the corresponding anode electrodes AE through the mask MSK. The pattern of the mask MSK may correspond to the patterns of the first to third light emitting layers EML1 to EML3. The cathode electrode CE may then be formed on the first to third light emitting layers EML1 to EML3.

In step (e.g., act or task) S3000 of forming the encapsulation layer on the light emitting element, the thin-film encapsulation layer TFE may be formed on the first to third light emitting elements LD1 to LD3. The lower layers of the thin-film encapsulation layer TFE may be passivated.

According to one or more embodiments, the sensing layer TS, the light-blocking layer LBP, and the color filter layer CFL may be arranged, and the display device DD according to one or more embodiments may be provided.

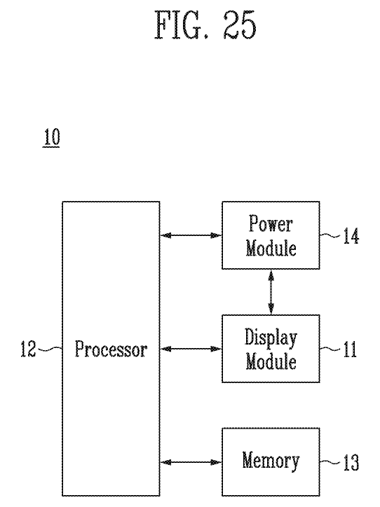

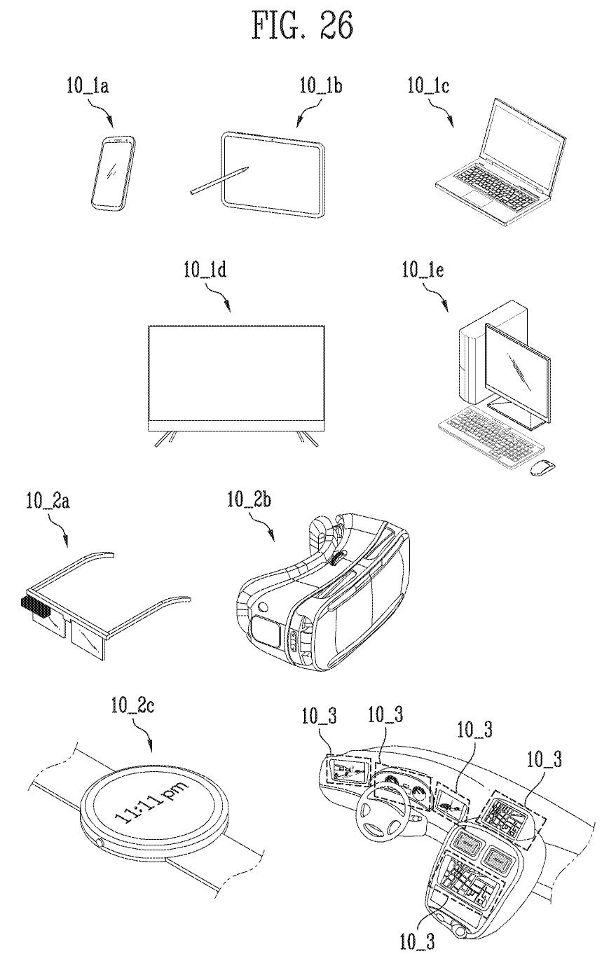

Hereinafter, with reference to FIGS. 25 and 26, an electronic device 10 including the display device DD manufactured according to the above-described method of manufacturing the display device DD will be described.

The display device DD according to one or more embodiments may be applied to one or more suitable electronic devices. An electronic device according to one or more embodiments may include the display device DD as described above, and may further include a module or a device having other additional functions besides the display device DD.

FIG. 25 is a block diagram of an electronic device 10 according to one or more embodiments of the present disclosure. Referring to FIG. 25, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data and/or information used to operate the processor 12 and/or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to one or more embodiments as described above. In addition, in terms of functionality, some of the individual modules included in one module may be included in a display device and others may be provided separately from the display device. For example, the display device may include the display module 11, and the processor 12, the memory 13, and the power module 14 may be provided as other devices in the electronic device 10, not in the display device.

FIG. 26 shows schematic views of various electronic devices according to one or more embodiments of the present disclosure.

Referring to FIG. 26, one or more suitable types (kinds) of electronic devices to which an embodiment of a display device of the present disclosure may be applied, include: an electronic device to display images such as a smartphone 10_1a, a tablet PC 10_1b, a laptop computer 10_1c, a television (TV) 10_1d, and/or a desktop monitor 10_1e; a wearable electronic device including a display module such as smart glasses 10_2a, a head-mounted display (HMD) 10_2b, and/or a smart watch 10_2c; and/or an automotive electronic device 10_3 including a display module such as a center information display (CID) arranged at the instrument cluster, the center fascia, and/or the dashboard, and/or a room mirror display (e.g., an electronic or digital rearview mirror) of a vehicle.

According to one or more embodiments of the present disclosure, a mask for deposition and a method of manufacturing the mask for deposition for improving the reliability of a deposition process may be provided.

According to one or more embodiments of the present disclosure, a mask for deposition and a method of manufacturing the mask for deposition which may reduce the risk of damage during an alignment process with a deposition target may be provided.

According to one or more embodiments of the present disclosure, an electronic device manufactured using the mask for deposition and having improved reliability may be provided. For example, the disclosed deposition mask structure—including the arrangement of substrate openings, oxide and pattern layers, and alignment marks—enables precise alignment and stable material deposition for forming light-emitting layers in display panels. These improvements directly contribute to enhanced manufacturing yield, reduced risk of component damage, and improved reliability of electronic devices such as smartphones, tablets, televisions, wearable devices, and/or automotive display systems.

In the context of the present application and unless otherwise defined, the terms "use," "using," and "used" may be considered synonymous with the terms "utilize," "utilizing," and "utilized," respectively.

"About" or "approximately" as used herein is inclusive of the stated value and may refers to within an acceptable range of deviation for the particular value as determined by one of ordinary skill in the art, considering the measurement in question and the error associated with measurement of the particular quantity (i.e., the limitations of the measurement system). For example, "about" may refer to within one or more standard deviations, or within ± 30%, ± 20%, ± 10%, or ± 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The display module, the display device, the electronic device/apparatus, the deposition mask-manufacturing apparatus, the vacuum-deposition apparatus such as a thermal deposition apparatus, an E-beam evaporator, a chemical vapor deposition apparatus, and/or the like, the device-manufacturing apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

The embodiments described above are provided to explain the present disclosure, but these embodiments are not intended to limit the scope of the present disclosure. It will be understood by those skilled in the art which one or more suitable changes, substitutions, and alternatives may be made therein without departing from the scope of the disclosure as set forth by the appended claims and their equivalents. Therefore, the technical scope of the present disclosure may be determined based on the scope of the accompanying claims and their functional equivalents.

What is claimed is:

1. A deposition mask, comprising:
a mask substrate having a first substrate opening and a second substrate opening defined therein;
an oxide layer on the mask substrate;
a first pattern layer on the oxide layer and having a pattern layer opening defined therein, the pattern layer opening overlapping with the first substrate opening;
a second pattern layer in the second substrate opening; and
an alignment mark in the second substrate opening.

2. The deposition mask of claim 1, wherein the second substrate opening is defined through the mask substrate.

3. The deposition mask of claim 1, wherein the alignment mark is positioned lower than the pattern layer opening.

4. The deposition mask of claim 1, wherein the second pattern layer is positioned lower than the pattern layer opening.

5. The deposition mask of claim 1, wherein the alignment mark is not in contact with the mask substrate.

6. The deposition mask of claim 1, wherein, in a cross-section view, the alignment mark is positioned between an upper surface and a lower surface of the mask substrate.

7. The deposition mask of claim 1, wherein the first pattern layer and the second pattern layer are formed in a same process.

8. The deposition mask of claim 1, wherein the oxide layer comprises a silicon oxide layer (SiOₓ), and
wherein the first pattern layer and the second pattern layer each comprise silicon nitride (SiNₓ)_{.}

9. The deposition mask of claim 1, wherein a lower surface of the second pattern layer is in contact with an upper surface of the alignment mark.

10. The deposition mask of claim 9, wherein the alignment mark comprises metal.

11. The deposition mask of claim 1, wherein an upper surface of the second pattern layer is in contact with a lower surface of the alignment mark.

12. The deposition mask of claim 1, wherein an alignment opening passing through the second pattern layer is defined in the second pattern layer, and
wherein the alignment mark is the alignment opening.

13. A method, comprising:
forming a groove in a base mask substrate;
forming a base oxide layer on the base mask substrate;
forming a base pattern layer on the base oxide layer;
forming an alignment mark in the groove; and
etching the base mask substrate to form a mask substrate having a first substrate opening and a second substrate opening defined therein,
wherein the alignment mark is arranged in the second substrate opening, and
the method is a method of manufacturing a deposition mask.

14. The method of claim 13, wherein the base pattern layer comprises:
a first pattern layer on the base oxide layer; and
a second pattern layer in the groove.

15. The method of claim 14, further comprising etching the base pattern layer,
wherein the base pattern layer is etched to define a pattern layer opening through which a deposition material passes, and
wherein the alignment mark is arranged lower than the pattern layer opening.

16. The method of claim 14, wherein the alignment mark is formed before the base pattern layer is formed, and
wherein an upper surface of the alignment mark is in contact with a lower surface of the second pattern layer.

17. The method of claim 14, wherein the alignment mark is formed after the base pattern layer is formed, and
wherein a lower surface of the alignment mark is in contact with an upper surface of the second pattern layer.

18. The method of claim 13, wherein the alignment mark comprises metal.

19. The method of claim 15, wherein the etching the base pattern layer further comprises etching the second pattern layer to form an alignment opening, and
wherein the alignment mark is the alignment opening.

20. An electronic device, comprising:
a display device comprising a display panel; and
a processor,
wherein the display panel comprises a light emitting layer, and
wherein the light emitting layer is deposited utilizing a deposition mask, the deposition mask comprising:
a mask substrate having a first substrate opening and a second substrate opening defined therein;
an oxide layer on the mask substrate;
a first pattern layer on the oxide layer and having a pattern layer opening defined therein, the pattern layer opening overlapping with the first substrate opening;
a second pattern layer in the second substrate opening; and
an alignment mark in the second substrate opening.
